(19) United States
(12) Patent Application Publication
(10) Pub. No.: US 2021/0233708 A1
(43) Pub. Date: Jul. 29, 2021

(54) INDUCTOR TRIMMING USING SACRIFICIAL MAGNETICALLY COUPLED LOOPS

(71) Applicant: Qorvo US, Inc., Greensboro, NC (US)

(72) Inventors: Dirk Robert Walter Leipold, San Jose, CA (US); George Maxim, Saratoga, CA (US); Baker Scott, San Jose, CA (US)

(21) Appl. No.: 16/751,827

(22) Filed: Jan. 24, 2020

(51) Int. Cl. H01F 41/04; H01L 23/64; H01L 49/02; H01F 27/28

(52) U.S. Cl. CPC H01F 41/045; H01L 23/645; H01F 2027/2809; H01F 27/2804; H01L 28/10

(57) ABSTRACT

Inductor trimming using sacrificial magnetically coupled loops is provided. Embodiments disclosed herein realize a trimmable inductor by using one or more magnetic sacrificial loops that are galvanically isolated from an adjacent primary loop of an inductor structure and which can be disabled by interrupting conduction in the sacrificial loop. When the magnetic sacrificial loop is closed, it magnetically couples to the primary loop and impacts an overall structure inductance. When conduction through the sacrificial loop is interrupted, there is no more magnetic coupling to the primary loop and there is no inductance impact from that particular sacrificial loop. The trimmable inductor can be permanently or temporarily trimmed. For example, conduction through the one or more sacrificial loops can be interrupted by removing a portion or the entire sacrificial loop (e.g., using a laser cut process). In other examples, conduction can be interrupted by a switching element, such as a transistor.

### FIELD OF THE DISCLOSURE

The present disclosure relates to parasitic impedance trimming for integrated circuits.

### BACKGROUND

Radio frequency (RF) devices, such as mobile communication devices, drive demand for increased signal processing capabilities in smaller packages.

As a result, increasingly complex integrated circuits (ICs) have been designed and manufactured to provide increasingly greater functionality in smaller footprints. There are many RF applications where a significant or even large performance variation exists. Such performance variation may be undesired, as in the case of poorly defined or modeled application environments or when RF devices are operated close to their maximum operating frequency. Alternatively, such performance variation may be desired, for example when a given circuit core is used to implement different versions of the same function but with slightly different performance that can be achieved with a trimming process (e.g., a dynamic or one-time trimming process).

Capacitor tuning and trimming is widely used in lower frequency RF applications. However, at higher frequencies (e.g., millimeter wave (mmWave) applications) capacitive trimming and tuning is less effective. Furthermore, not all circuit performance can be effectively impacted with capacitive or active device tuning or trimming.

### SUMMARY

Inductor trimming using sacrificial magnetically coupled loops is provided. Embodiments disclosed herein realize a trimmable inductor by using one or more magnetic sacrificial loops that are galvanically isolated from an adjacent primary loop of an inductor structure and which can be disabled by interrupting conduction in the sacrificial loop. When the magnetic sacrificial loop is closed, it magnetically couples to the primary loop and impacts an overall structure inductance. When conduction through the sacrificial loop is interrupted, there is no more magnetic coupling to the primary loop and there is no inductance impact from that particular sacrificial loop.

The trimmable inductor can be permanently or temporarily trimmed. For example, conduction through the one or more sacrificial loops can be interrupted by removing a portion or the entire sacrificial loop (e.g., using a laser cut process). In other examples, conduction can be interrupted by a switching element, such as a transistor. The sacrificial loops may be placed inside the primary loop, outside the primary loop, or both inside and outside. The position of the sacrificial loops can give the direction of the magnetic coupling (e.g., additive or subtractive).

This inductor trimming technique can be used in various applications, such as integrated circuits (ICs), integrated passive devices (IPDs), laminates, redistribution layers (e.g., wafer-fan-out or wafer-fan-in), and so on. The trimmable inductor can be useful in a wide range of applications. For example, with amplifiers that do not have a well-defined ground degeneration inductance, the trimmable inductor can reduce or compensate for such variability. In a circuit that operates close to a transition frequency of active devices, the trimmable inductor can help stabilize the performance of the circuit. In a circuit with passive devices that operate closer to their self-resonant frequency, the trimmable inductor can also help stabilize the performance of the circuit. The trimming of the inductance can be used to calibrate the gain and/or the linearity of an amplifier (low-noise amplifier, driver, or power amplifier). It can also be used in variable gain amplifiers (VGAs), programmable gain amplifiers (PGAs) or digital gain amplifiers (DGAs).

An exemplary embodiment provides a trimmable inductor. The trimmable inductor includes a primary loop. The trimmable inductor further includes a first sacrificial loop disposed adjacent the primary loop, galvanically isolated from the primary loop, and configured to magnetically couple to the primary loop. The trimmable inductor is configured to be trimmed by interrupting conduction through the first sacrificial loop such that a current in the primary loop no longer induces a current in the first sacrificial loop.

Another exemplary embodiment provides an IC. The IC includes a substrate and a trimmable inductor disposed over the substrate. The trimmable inductor includes a primary loop and one or more sacrificial loops positioned adjacent the primary loop and galvanically isolated from the primary loop. The trimmable inductor is configured to be trimmed by interrupting conduction through the one or more sacrificial loops such that a current in the primary loop does not induce a current in the one or more sacrificial loops.

Another exemplary embodiment provides a method for providing an inductor in an IC. The method includes providing a trimmable inductor over a substrate, the trimmable inductor comprising a primary loop and a first sacrificial loop adjacent the primary loop and galvanically isolated from the primary loop. The method further includes trimming the trimmable inductor by interrupting conduction through the first sacrificial loop such that a current in the primary loop no longer induces a current in the first sacrificial loop.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a schematic diagram of an exemplary integrated circuit (IC) having a trimmable inductor.

FIG. 1B is a schematic diagram of another exemplary IC with the trimmable inductor having a magnetic primary loop and one or more magnetic sacrificial loops.

FIG. 2A is a schematic diagram of an exemplary trimmable inductor according to embodiments of the present disclosure.

FIG. 2B is a schematic diagram of another exemplary trimmable inductor.

FIG. 3 is a three-dimensional view of another exemplary trimmable inductor.

FIG. 4A is a graphical representation of inductance of the trimmable inductor of FIG. 3 at two inductance values.

FIG. 4B is a graphical representation of quality (Q) factor of the trimmable inductor of FIG. 3 at two inductance values.

FIG. 5 is a three-dimensional view of another exemplary trimmable inductor.

FIG. 6A is a graphical representation of inductance of the trimmable inductor of FIG. 5 at three inductance values.

FIG. 6B is a graphical representation of Q factor of the trimmable inductor of FIG. 5 at three inductance values.

FIG. 7A is a schematic diagram of another exemplary trimmable inductor with switchable sacrificial loops.

FIG. 7B is a schematic diagram of another exemplary trimmable inductor with switchable sacrificial loops.

FIG. 8 is a graphical representation of another exemplary trimmable inductor with a sacrificial loop surrounding the primary loop.

FIG. 9A is a graphical representation of inductance of the trimmable inductor of FIG. 8.

FIG. 9B is a graphical representation of Q factor of the trimmable inductor of FIG. 8.

FIG. 10 is a flow diagram illustrating a process for providing an inductor in an IC.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the

Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Inductor trimming using sacrificial magnetically coupled loops is provided. Embodiments disclosed herein realize a trimmable inductor by using one or more magnetic sacrificial loops that are galvanically isolated from an adjacent primary loop of an inductor structure and which can be disabled by interrupting conduction in the sacrificial loop. When the magnetic sacrificial loop is closed, it magnetically couples to the primary loop and impacts an overall structure inductance. When conduction through the sacrificial loop is interrupted, there is no more magnetic coupling to the primary loop and there is no inductance impact from that particular sacrificial loop.

The trimmable inductor can be permanently or temporarily trimmed. For example, conduction through the one or more sacrificial loops can be interrupted by removing a portion or the entire sacrificial loop (e.g., using a laser cut process). In other examples, conduction can be interrupted by a switching element, such as a transistor. The sacrificial loops may be placed inside the primary loop, outside the primary loop, or both inside and outside. The position of the sacrificial loops can give the direction of the magnetic coupling (e.g., additive or subtractive).

This inductor trimming technique can be used in various applications, such as integrated circuits (ICs), integrated passive devices (IPDs), laminates, redistribution layers (e.g., wafer-fan-out or wafer-fan-in), and so on. The trimmable inductor can be useful in a wide range of applications. For example, with amplifiers that do not have a well-defined ground degeneration inductance, the trimmable inductor can reduce or compensate for such variability. In a circuit that operates close to a transition frequency of active devices, the trimmable inductor can help stabilize the performance of the circuit. In a circuit with passive devices that operate closer to their self-resonant frequency, the trimmable inductor can also help stabilize the performance of the circuit. The trimming of the inductance can be used to calibrate the gain and/or the linearity of an amplifier (low-noise amplifier, driver, or power amplifier). It can also be used in variable gain amplifiers (VGAs), programmable gain amplifiers (PGAs) or digital gain amplifiers (DGAs).

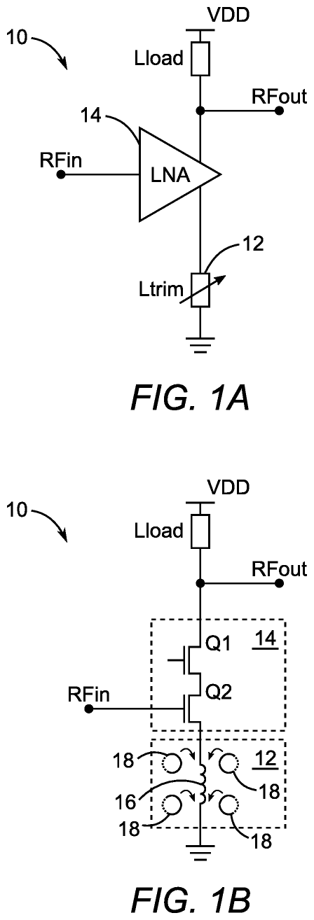

FIG. 1 A is a schematic diagram of an exemplary IC 10 having a trimmable inductor 12. In many ICs 10, particularly in radio frequency (RF) applications, capacitive and other traditional impedance trimming approaches are insufficient to achieve desired performance. Capacitor tuning and trimming is widely used at lower RF frequencies. However, at higher frequencies (e.g., millimeter wave (mmWave) applications) capacitive trimming and tuning is less effective. Furthermore, not all circuit performance can be effectively impacted with a capacitive or active device tuning or trimming. In some cases, a true inductance trimming or tuning is mandated. In this regard, the trimmable inductor 12 is provided to facilitate inductive trimming in ICs 10.

For example, the IC 10 includes a low noise amplifier (LNA) 14, in which parasitic and other inductance in the IC 10 has a large impact on the performance of the LNA 14. The LNA 14 has a source degeneration inductance which impacts both the gain and linearity of the IC 10. The trimmable inductor 12 provides inductance trimming, which facilitates reduced performance variation and higher yields for a given manufacturing process.

In addition, the trimmable inductor 12 can be used to create different modes of operation. For example, an IC 10 for a multi-band receiver may use a number of different magnetic inductors with a common active device core. The active device core is generally wide-band and can be used for a number of specific frequency band applications. The magnetic inductors can be connected to the active device core to provide amplifier performance in each operating band of the multi-band receiver. In such examples, the trimmable inductor 12 can customize these inductors in-situ in order to optimize and accelerate the design of the multi-band receiver.

FIG. 1B is a schematic diagram of another exemplary IC 10 with the trimmable inductor 12 having a magnetic primary loop 16 and one or more magnetic sacrificial loops 18. The IC 10 of FIG. 1B is similar to the IC 10 of FIG. 1A, and is illustrated with the LNA 14 including amplifying transistors Q1, Q2. The inductance of a structure, such as the trimmable inductor 12, is dependent not only on the primary loop 16, but also on any nearby magnetic loop which may couple magnetically to the primary loop 16. In this regard, the trimmable inductor 12 includes the one or more magnetic sacrificial loops 18 disposed adjacent the primary loop 16. Each of the sacrificial loops 18 is galvanically isolated from the primary loop 16 and configured to magnetically couple to the primary loop 16.

The inductance value of the trimmable inductor 12 can be modified by interrupting conduction through one or more of the sacrificial loops 18. When a sacrificial loop 18 is continuous, the magnetic field of the primary loop 16 will induce a current in the sacrificial loop 18, which will in turn impact inductance through the primary loop 16. When conduction through the sacrificial loop 18 is interrupted (e.g., through cutting or switching) there is no induced current in the sacrificial loop 18 and thus it no longer impacts the inductance through the primary loop 16.

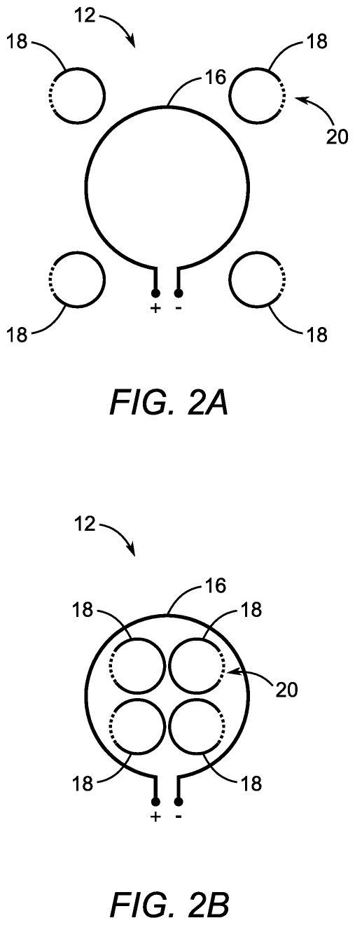

FIG. 2A is a schematic diagram of an exemplary trimmable inductor 12 according to embodiments of the present disclosure. As described above, the trimmable inductor 12 can be trimmed between two or more inductance values by interrupting conduction through one or more sacrificial loops 18. In the illustrated example, conduction through the sacrificial loops 18 is interrupted by removing a portion (or all) of the sacrificial loop 18. In some examples, a portion of the sacrificial loop 18 is removed through laser cutting, etching, drilling, or similar approaches to create a gap 20 in the sacrificial loop 18.

Generally, these approaches of removing a portion of the sacrificial loop 18 can be done only once per sacrificial loop 18 to permanently interrupt conduction through the sacrificial loop 18. This may be appropriate for trimming the trimmable inductor 12 during manufacturing of the IC 10 of FIGS. 1A and 1B. In the illustrated example, the sacrificial loops 18 are placed outside the primary loop 16, which may require a larger area for the trimmable inductor 12 than traditional inductors.

FIG. 2B is a schematic diagram of another exemplary trimmable inductor 12. Some embodiments of the trimmable inductor 12 have sacrificial loops 18 placed inside the primary loop 16 rather than outside the primary loop 16 (as illustrated in FIG. 2A). This can provide a significantly smaller area for the trimmable inductor 12, which may be comparable to traditional inductors.

It should be understood that FIGS. 2A and 2B are exemplary in nature, and embodiments of the trimmable inductor 12 can be implemented differently. For example, the sacrificial loops 18 may provide different degrees of inductance trimming. In some embodiments, the sacrificial loops 18 may have different lengths, be spaced a different distance apart from the primary loop 16, or otherwise disposed differently to provide different inductance levels through trimming different sacrificial loops 18 or combinations of sacrificial loops 18. In some embodiments, sacrificial loops 18 can be placed both inside and outside the primary loop 16. This may provide for both additive and subtractive inductance trimming, depending on the position of a given sacrificial loop 18 inside or outside the primary loop 16.

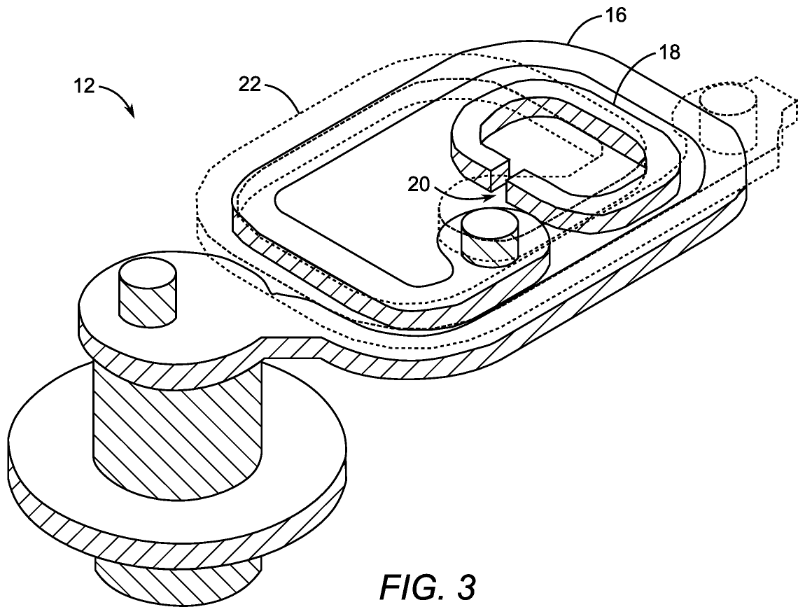

FIG. 3 is a three-dimensional view of another exemplary trimmable inductor 12. In the illustrated embodiment, the trimmable inductor 12 has a single sacrificial loop 18 disposed inside the primary loop 16. The sacrificial loop 18 may be used to achieve a two value inductor trimming: the value in presence of the sacrificial loop 18 (closed) and the value when the sacrificial loop 18 is open (e.g., cut to produce a gap 20).

The primary loop 16 may be realized in one, two, or more metal layers (e.g., including an upper layer 22 of the primary loop 16). In some examples, the sacrificial loop 18 is realized in a single metal layer for ease of cutting. The sacrificial loop 18 may be realized in the same metal layer with the primary loop 16 or it may be realized in adjacent metal layers. It should be noted that the sacrificial loop 18 is galvanically isolated from the primary loop 16, such that it is magnetically coupled to the primary loop 16 but is at an electrical potential which does not depend on the primary loop 16 (e.g., a floating potential relative to the primary loop 16).

In an exemplary aspect, the trimmable inductor 12 is formed in a three-dimensional (3D) packaging with one or more redistribution layers, such as fan-out wafer-level packaging (FOWLP), fan-out panel-level packaging (FOPLP), fan-in wafer-level packaging (FIWLP), fan-in panel-level packaging (FIPLP), or wafer-level chip scale packaging (WLCSP). Similar techniques can be used in other processes including active or passive IC processes, laminates, 3D printing, low temperature co-fired ceramics (LTCC), and so on. The illustrated example includes two redistribution layers, but more or fewer metallization layers may be used in other examples.

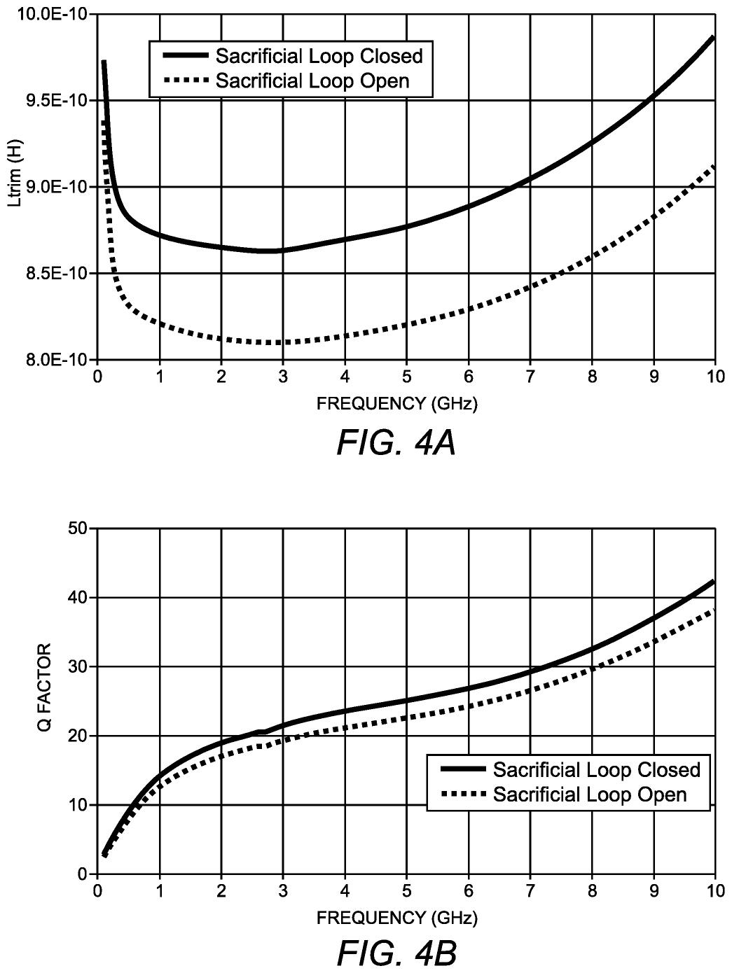

FIG. 4A is a graphical representation of inductance of the trimmable inductor 12 of FIG. 3 at two inductance values. The trimmable inductor 12 provides a first inductance value with the sacrificial loop 18 closed (e.g., magnetically coupled to the primary loop 16 and conducting current) and a second inductance value when the sacrificial loop 18 is open (e.g., with conduction interrupted by removing a portion of the sacrificial loop 18).

FIG. 4B is a graphical representation of quality (Q) factor of the trimmable inductor 12 of FIG. 3 at two inductance values. The Q factor of the trimmable inductor 12 is minimally impacted by trimming—by less than 5% across an operating RF band of the IC 10 in which the trimmable inductor 12 is implemented.

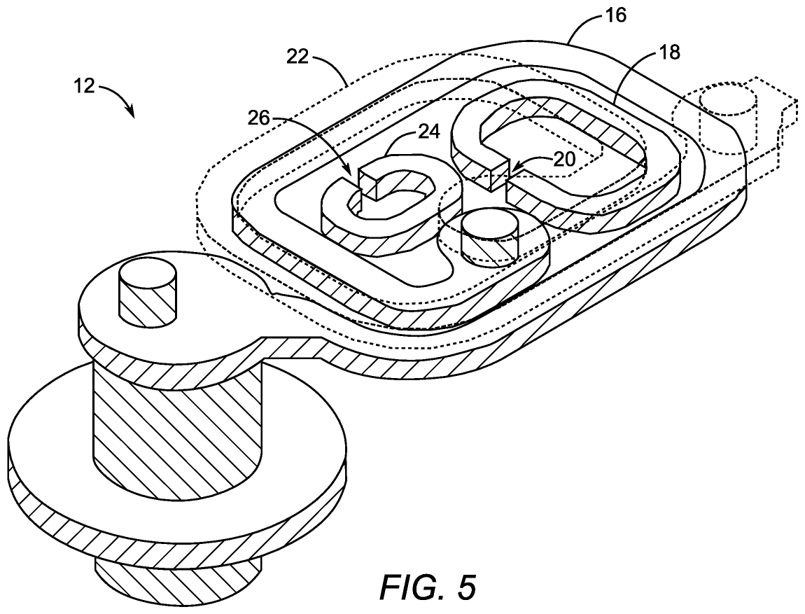

FIG. 5 is a three-dimensional view of another exemplary trimmable inductor 12. In the illustrated embodiment, the trimmable inductor 12 has two sacrificial loops 18, 24 disposed inside the primary loop 16. The use of multiple sacrificial loops 18 facilitates three or more value inductor trimming through combinations of cuts in different sacrificial loops 18.

In an exemplary aspect, the trimmable inductor 12 includes a first sacrificial loop 18 having a first length and a second sacrificial loop 24 with a different second length. The trimmable inductor 12 thus provides a variety of trimmed inductance values by cutting the first sacrificial loop 18 (to produce a first gap 20), cutting the second sacrificial loop 24 (to produce a second gap 26), or by cutting both sacrificial loops 18, 24.

In some examples, the sacrificial loops 18, 24 may have a same length and still provide multiple trimmed inductance values. Further embodiments can include additional sacrificial loops 18, 24, including with sacrificial loops 18, 24 being disposed inside and outside the primary loop 16. It should be noted that, as with the embodiment of FIG. 3, each of the first sacrificial loop 18 and the second sacrificial loop 24 is galvanically isolated from the primary loop 16, and may further be galvanically isolated from one another.

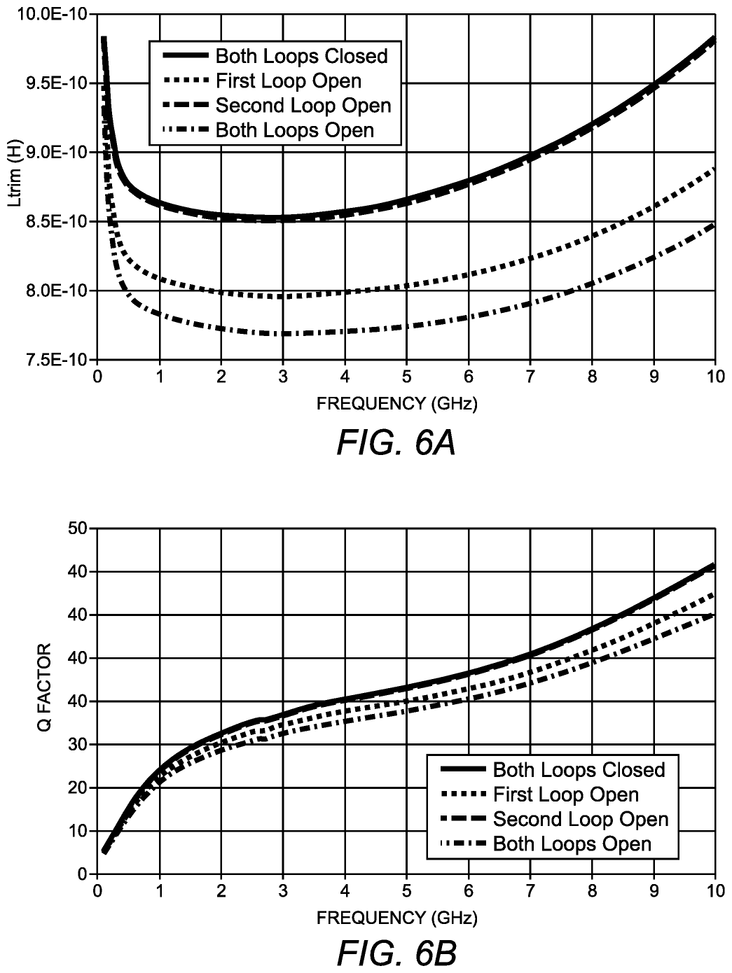

FIG. 6A is a graphical representation of inductance of the trimmable inductor 12 of FIG. 5 at multiple inductance values. The trimmable inductor 12 provides a first inductance value with both sacrificial loops 18, 24 closed, a second inductance value with the first sacrificial loop 18 open, a third inductance value with the second sacrificial loop 24 open, and a fourth inductance value with both sacrificial loops 18, 24 open.

FIG. 6B is a graphical representation of Q factor of the trimmable inductor 12 of FIG. 5 at three inductance values. Q factor is again minimally impacted by the different trimmed inductance values of the trimmable inductor 12.

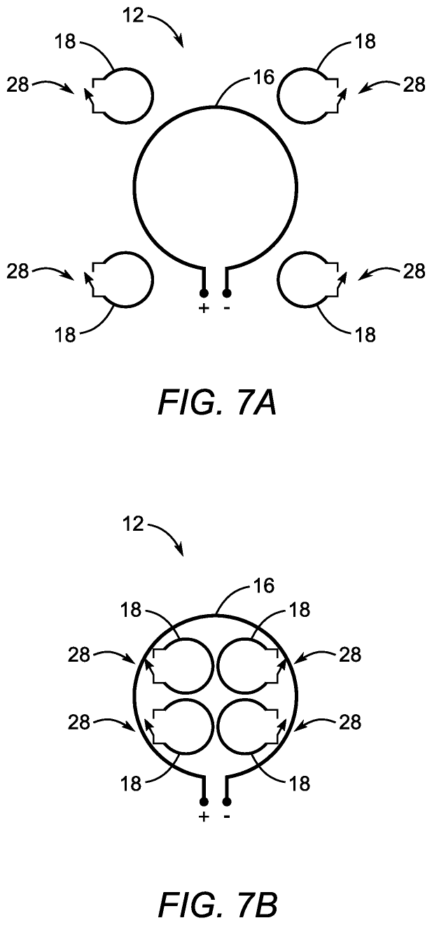

FIG. 7A is a schematic diagram of another exemplary trimmable inductor 12 with switchable sacrificial loops 18. FIG. 7B is a schematic diagram of another exemplary trimmable inductor 12 with switchable sacrificial loops 18. As illustrated in FIGS. 7A and 7B, trimming of the trimmable inductor 12 can be achieved through other approaches than forming gaps 20, 26 through destructive processes as in the embodiments of FIGS. 3 and 5.

For example, each sacrificial loop 18 can include a switching element 28 which can selectively interrupt conduction through the sacrificial loop 18. The switching element 28 can be a transistor (e.g., a field effect transistor (FET), bipolar junction transistor (BJT), etc.), a thyristor, a volatile or non-volatile memory controlled device, and so on.

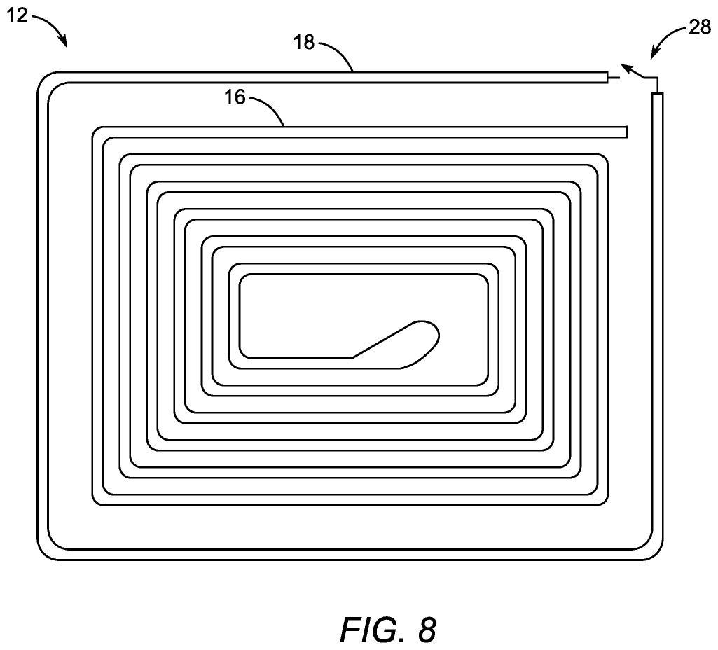

FIG. 8 is a graphical representation of another exemplary trimmable inductor 12 with a sacrificial loop 18 surrounding the primary loop 16. Conduction through the sacrificial loop 18 can be interrupted by the switching element 28. In other examples, a portion of the sacrificial loop 18 can be removed instead.

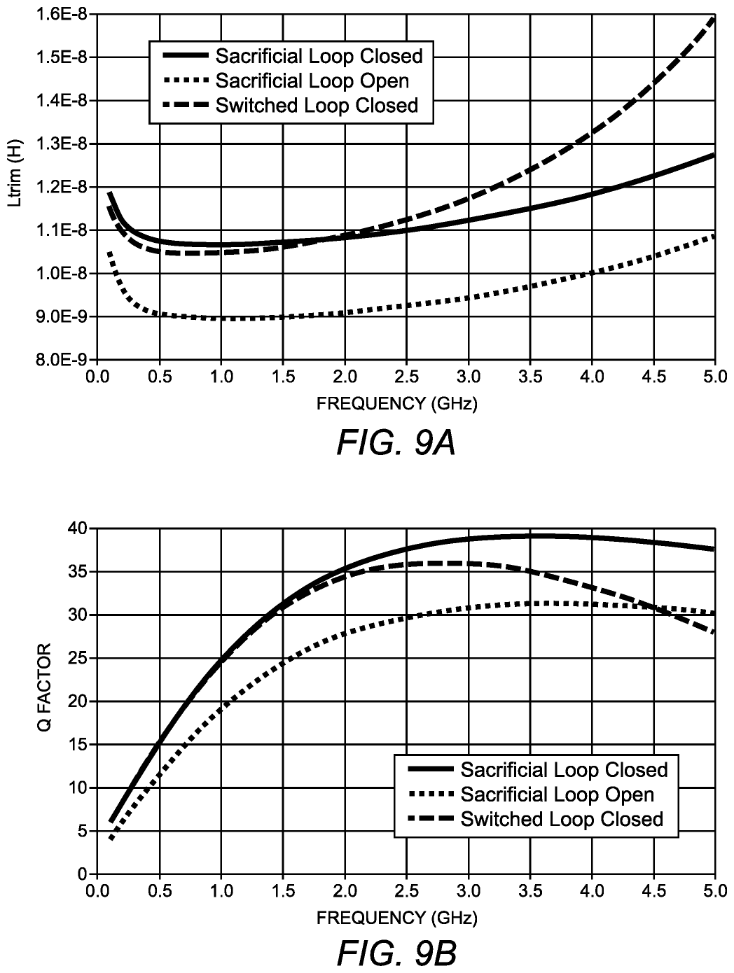

FIG. 9A is a graphical representation of inductance of the trimmable inductor 12 of FIGS. 3 and 8. For the trimmable inductor 12 of FIG. 3 without the switching element 28, a first inductance value is illustrated with the sacrificial loop 18 closed. A second inductance value is illustrated with the sacrificial loop 18 open, which applies to the embodiments of both FIGS. 3 and 8. For the trimmable inductor 12 of FIG. 8 with the switching element 28, a third inductance value is illustrated with the sacrificial loop 18 closed.

FIG. 9B is a graphical representation of Q factor of the trimmable inductor 12 of FIG. 8. In the embodiment of FIG. 8 with the switching element 28, the Q factor is degraded when the sacrificial loop 18 is closed. This is due to the use of an active switching element 28, which does not conduct the entire induced current from the primary loop 16. In other embodiments, this effect may be mitigated through use of different switching elements 28.

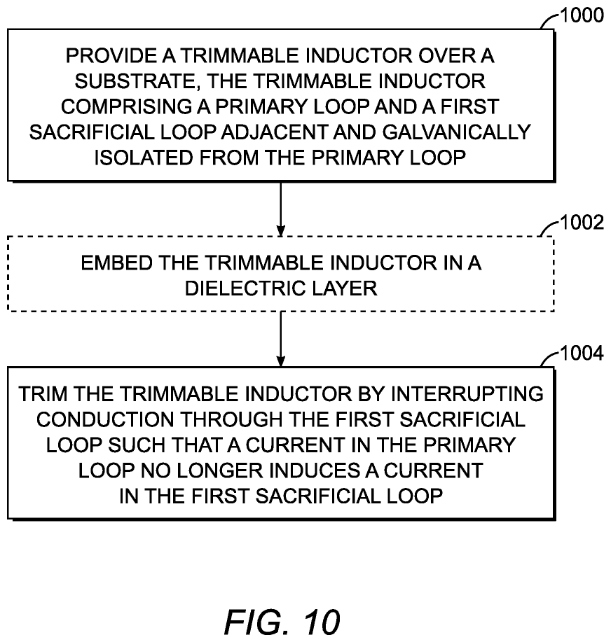

FIG. 10 is a flow diagram illustrating a process for providing an inductor in an IC. Dashed boxes represent optional steps. The process begins at operation 1000, with providing a trimmable inductor over a substrate, the trimmable inductor comprising a primary loop and a first sacrificial loop adjacent the primary loop and galvanically isolated from the primary loop. The process may optionally continue at operation 1002, with embedding the trimmable inductor in a dielectric layer. The dielectric layer may form part of a redistribution layer or may be formed as a passivation layer in an integrated passive device or integrated active device process. The process continues at operation 1004, with trimming the trimmable inductor by interrupting conduction through the first sacrificial loop such that a current in the primary loop no longer induces a current in the first sacrificial loop. In some examples, trimming is performed without removing the dielectric layer (e.g., by laser cutting). In some examples, the trimming is performed after partially removing the dielectric layer.

Although the operations of FIG. 10 are illustrated in a series, this is for illustrative purposes and the operations are not necessarily order dependent. Some operations may be performed in a different order than that presented. For example, operation 1002 may be performed after operation 1004, such that the trimmable inductor is embedded in a dielectric layer after trimming. Further, processes within the scope of this disclosure may include fewer or more steps than those illustrated in FIG. 10.

In an exemplary aspect, where operation 1002 is performed, the trimmable inductor is embedded in the dielectric layer by depositing the primary loop over the substrate, depositing the first sacrificial loop over the substrate, and depositing the dielectric layer over the primary loop and the first sacrificial loop.

In another exemplary aspect, a second and additional sacrificial loops are deposited adjacent the primary loop and may be selectively opened (e.g., through cutting or a switch) to provide inductive trimming.

The dielectric layer can be formed with an appropriate dielectric material for a given process. In embodiments where the trimmable inductor is provided in a redistribution layer, the dielectric material can include polyimide, polynorbornenes, benzocyclobutene (BCB), polytetrafluoroethylene (PTFE), hydrogen silsesquioxane (HSQ), methylsilsesquioxane (MSQ), and other polymers. In other embodiments, the dielectric layer can be an oxide (e.g., silicon dioxide) or other passivation layer. The primary loop and the sacrificial loops can be formed from a same or different metals, such as copper, gold, silver, aluminum, tin, and combinations or alloys thereof.

Those skilled in the art will recognize improvements and modifications to the preferred embodiments of the present disclosure. All such improvements and modifications are considered within the scope of the concepts disclosed herein and the claims that follow.

What is claimed is:

1. A trimmable inductor, comprising:
a primary loop; and
a first sacrificial loop disposed adjacent the primary loop, galvanically isolated from the primary loop, and configured to magnetically couple to the primary loop;
wherein the trimmable inductor is configured to be trimmed by interrupting conduction through the first sacrificial loop such that a current in the primary loop no longer induces a current in the first sacrificial loop.

2. The trimmable inductor of claim 1, wherein conduction through the first sacrificial loop is interrupted by removing at least a portion of the first sacrificial loop.

3. The trimmable inductor of claim 1, wherein conduction through the first sacrificial loop is interrupted by a switching element in the first sacrificial loop.

4. The trimmable inductor of claim 3, wherein the first sacrificial loop electrically floats relative to the primary loop.

5. The trimmable inductor of claim 1, wherein the trimmable inductor can be trimmed between two or more inductance values.

6. The trimmable inductor of claim 1, wherein the first sacrificial loop is further disposed inside the primary loop.

7. The trimmable inductor of claim 1, wherein the first sacrificial loop is further disposed outside the primary loop.

8. The trimmable inductor of claim 1, further comprising a second sacrificial loop disposed adjacent the primary loop, galvanically isolated from the primary loop and the first sacrificial loop, and configured to magnetically couple to the primary loop.

9. The trimmable inductor of claim 8, wherein the trimmable inductor can be trimmed between three or more inductance values by selectively interrupting conduction through the first sacrificial loop, the second sacrificial loop, or both the first sacrificial loop and the second sacrificial loop.

10. The trimmable inductor of claim 8, wherein:
the first sacrificial loop is further disposed inside the primary loop; and
the second sacrificial loop is further disposed outside the primary loop.

11. The trimmable inductor of claim 8, wherein the second sacrificial loop has a different length than the first sacrificial loop.

12. The trimmable inductor of claim 8, wherein the second sacrificial loop is spaced a different distance apart from the primary loop than the first sacrificial loop.

13. The trimmable inductor of claim 1, further comprising a dielectric layer surrounding the primary loop and the first sacrificial loop.

14. The trimmable inductor of claim 13, wherein:
the dielectric layer comprises at least one of polyimide, a polynorbornene, benzocyclobutene (BCB), polytetrafluoroethylene (PTFE), hydrogen silsesquioxane (HSQ), or methylsilsesquioxane (MSQ); and
the first sacrificial loop comprises at least one of copper, gold, silver, aluminum, or tin.

15. An integrated circuit, comprising:
a substrate; and
a trimmable inductor disposed over the substrate and comprising:
a primary loop; and
one or more sacrificial loops positioned adjacent the primary loop and galvanically isolated from the primary loop;
wherein the trimmable inductor is configured to be trimmed by interrupting conduction through the one or more sacrificial loops such that a current in the primary loop does not induce a current in the one or more sacrificial loops.

16. The integrated circuit of claim 15, wherein the trimmable inductor can be trimmed between two or more inductance values by selectively destroying a portion of at least one of the one or more sacrificial loops.

17. The integrated circuit of claim 15, wherein the trimmable inductor is provided in a redistribution layer of the integrated circuit.

18. The integrated circuit of claim 15, wherein the trimmable inductor is laminated to the substrate.

19. The integrated circuit of claim 15, wherein the trimmable inductor is three-dimensionally (3D) printed over the substrate.

20. A method for providing an inductor in an integrated circuit, the method comprising:
providing a trimmable inductor over a substrate, the trimmable inductor comprising a primary loop and a first sacrificial loop adjacent and galvanically isolated from the primary loop; and
trimming the trimmable inductor by interrupting conduction through the first sacrificial loop such that a current in the primary loop no longer induces a current in the first sacrificial loop.
